(19) United States
(12) Patent Application Publication
(10) Pub. No.: US 2016/0014356 A1
(43) Pub. Date: Jan. 14, 2016

(54) SOLID-STATE IMAGING DEVICE AND METHOD OF DRIVING SOLID-STATE IMAGING DEVICE

(71) Applicant: CANON KABUSHIKI KAISHA, Tokyo (JP)

(72) Inventor: Takamasa Sakuragi, Machida-shi (JP)

(21) Appl. No.: 14/751,926

(22) Filed: Jun. 26, 2015

(30) Foreign Application Priority Data
Jul. 8, 2014 (JP) 2014-140480

(51) Int. Cl. H04N 5/357; H04N 5/378; H04N 5/3745; H01L 27/146

(52) U.S. Cl. CPC H04N 5/3577; H01L 27/14636; H01L 27/14609; H04N 5/378; H04N 5/37457

(57) ABSTRACT

A solid-state imaging device includes a plurality of pixels each of which has a photoelectric conversion element and a pixel output portion and which are arranged in a column direction, a first wiring connected to the pixel output portions of the plurality of pixels, a differential amplifier circuit whose one input terminal is connected to the first wiring, a second wiring connected to the other input terminal of the differential amplifier circuit, a third wiring which is formed so as to extend in the column direction and is connected to a first pad, a plurality of switches connected between the second and third wirings, and a control unit for driving the switch at a position corresponding to the position of the pixel in which the pixel output portion is driven in association with the driving of the pixel output portion.

### BACKGROUND OF THE INVENTION

1. Field of the Invention

The present invention relates to a solid-state imaging device and a method of driving a solid-state imaging device.

2. Description of the Related Art

Since a solid-state imaging device using a sensor such as CCD, CMOS sensor, or the like is mounted in a video camera, a surveillance camera, or the like and is used under various environments, it is subjected to an electric field and a magnetic field under such environments. When a magnetic field is applied to the solid-state imaging device, a magnetically induced voltage according to a Faraday's law is generated on wirings in the solid-state imaging device and becomes a cause of deterioration of a picture quality. Therefore, a magnetic noise countermeasure technique to suppress an influence of the electromagnetic field is demanded.

Japanese Patent Application Laid-Open No. 2008-085994 discloses a method whereby a reference voltage supplied to a read-out circuit for reading out a signal from a pixel is electrically separated from the outside of a solid-state imaging device by using a sample and hold circuit and an area intersecting with an external magnetic field is reduced, thereby decreasing a magnetically induced voltage.

Japanese Patent Application Laid-Open No. 2012-253740 discloses a method whereby a difference between a pixel signal which is input from a signal line connected to a valid pixel and a pixel signal which is input from a signal line connected to a reference pixel is processed, thereby reducing noises of a signal which is output from a read-out circuit.

However, according to the method disclosed in Japanese Patent Application Laid-Open No. 2008-085994, although the magnetically induced voltage which is superimposed to the reference voltage can be suppressed, a magnetically induced voltage which is generated on a signal line for transmitting the signal from the pixel cannot be suppressed. Therefore, even if a difference between the pixel output signal and the reference voltage is obtained, noises remain and are output as they are from the read-out circuit.

According to the method disclosed in Japanese Patent Application Laid-Open No. 2012-253740, there is a possibility that magnetically induced voltages which are generated on two signal lines can be cancelled by a differential operation. However, actually, since distances to the read-out circuits of the two signal lines differ, the magnetically induced voltages which are generated on the two signal lines are not equal, and even if a difference is obtained in the read-out circuits, it is difficult to cancel it.

### SUMMARY OF THE INVENTION

It is an aspect of the invention to provide a solid-state imaging device which can effectively suppress a noise component caused by an external magnetic field which is superimposed to an output signal of a read-out circuit and a method of driving such a device.

According to an aspect of the invention, there is provided a solid-state imaging device including a first pixel and a second pixel each of which has a photoelectric conversion element and a pixel output portion for outputting a signal based on a signal generated by the photoelectric conversion element and which are arranged in a first direction, a first wiring which is connected to the pixel output portion of each of the first pixel and the second pixel and is arranged along the first direction, a differential amplifier circuit in which one input terminal is connected to the first wiring and a length of an electric path of the first wiring from the one input terminal to the pixel output portion of the second pixel is longer than a length of an electric path of the first wiring from the one input terminal to the pixel output portion of the first pixel, a second wiring connected to the other input terminal of the differential amplifier circuit, a first pad to which a voltage is supplied, a third wiring which is formed along the first direction and is connected to the first pad, a first switch arranged on an electric path between the second wiring and the third wiring, a second switch which is arranged on the electric path between the second wiring and the third wiring electrically in parallel with the first switch and in which a length of an electric path from the other input terminal to the first pad via the second wiring and the third wiring is longer than that in the case where the first switch is in ON state, and a control unit configured to control the first switch to be ON state and the second switch to be OFF state in a case the pixel output portion of the first pixel outputs the signal to the first wiring, and to control the second switch to be ON state and the first switch to be OFF state in a case the pixel output portion of the second pixel outputs the signal to the first wiring.

According to another aspect of the invention, there is provided a method of driving a solid-state imaging device including a first pixel and a second pixel each of which has a photoelectric conversion element and a pixel output portion for outputting a signal based on a signal generated by the photoelectric conversion element and which are arranged in a first direction, a first wiring which is connected to the pixel output portion of each of the first pixel and the second pixel and is arranged along the first direction, a differential amplifier circuit in which one input terminal is connected to the first wiring and a length of an electric path of the first wiring from the one input terminal to the pixel output portion of the second pixel is longer than a length of an electric path of the first wiring from the one input terminal to the pixel output portion of the first pixel, a second wiring connected to the other input terminal of the differential amplifier circuit, and a third wiring which is formed along the first direction and is connected to a first pad, wherein the method includes setting a length of the electric path from the other input terminal to the first pad through the third wiring to a first length in the case where the pixel output portion of the first pixel outputs the signal to the first wiring, and setting a length of the electric path from the other input terminal to the first pad through the third wiring to a second length longer than the first length in the case where the pixel output portion of the second pixel outputs the signal to the first wiring.

Further features of the present invention will become apparent from the following description of exemplary embodiments with reference to the attached drawings.

### BRIEF DESCRIPTION OF THE DRAWINGS

FIG. 1 is a circuit diagram illustrating a construction of a solid-state imaging device according to a first embodiment of the present invention.

FIG. 2 is a circuit diagram illustrating a construction of a unit pixel of the solid-state imaging device according to the first embodiment of the present invention.

FIG. 3 is a timing chart illustrating a method of driving the solid-state imaging device according to the first embodiment of the present invention.

FIGS. 4A and 4B are schematic cross-sectional views illustrating the solid-state imaging device in a state where it has been put on an external substrate.

FIG. 5 is a circuit diagram illustrating a construction of a solid-state imaging device according to a second embodiment of the present invention.

FIG. 6 is an equivalent circuit diagram of a ground loop in the solid-state imaging device according to the second embodiment of the present invention.

FIG. 7 is a block diagram illustrating a construction of an imaging system according to a third embodiment of the present invention.

FIG. 8 is a circuit diagram illustrating a construction of a solid-state imaging device according to a modification of the embodiments of the present invention.

### DESCRIPTION OF THE EMBODIMENTS

Preferred Embodiments of the Present Invention will now be described in detail in accordance with the accompanying drawings.

### First Embodiment

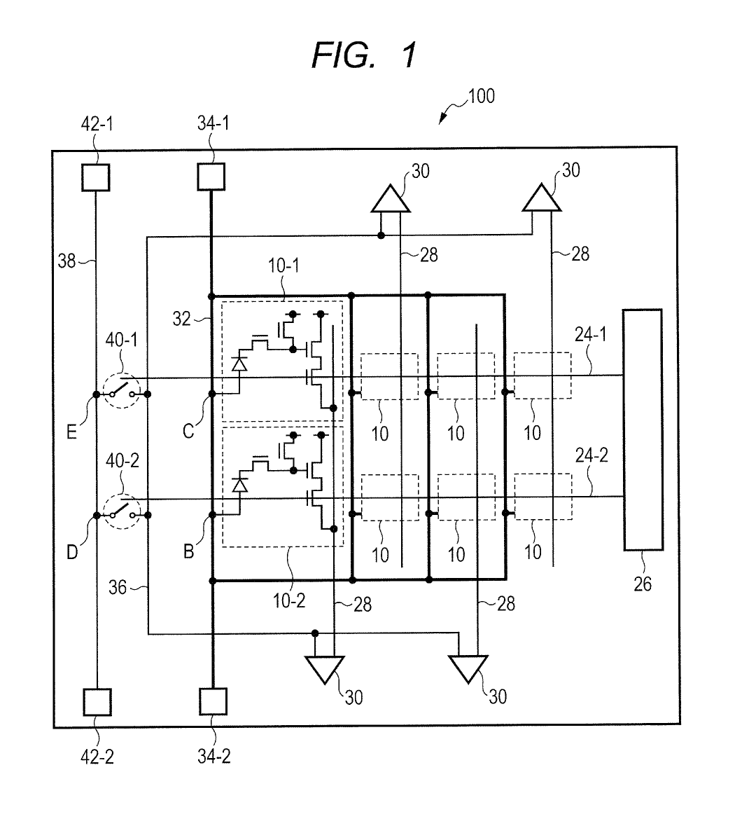

A solid-state imaging device and a method of driving the same according to a first embodiment of the present invention will be described with reference to FIGS. 1 to 4B.

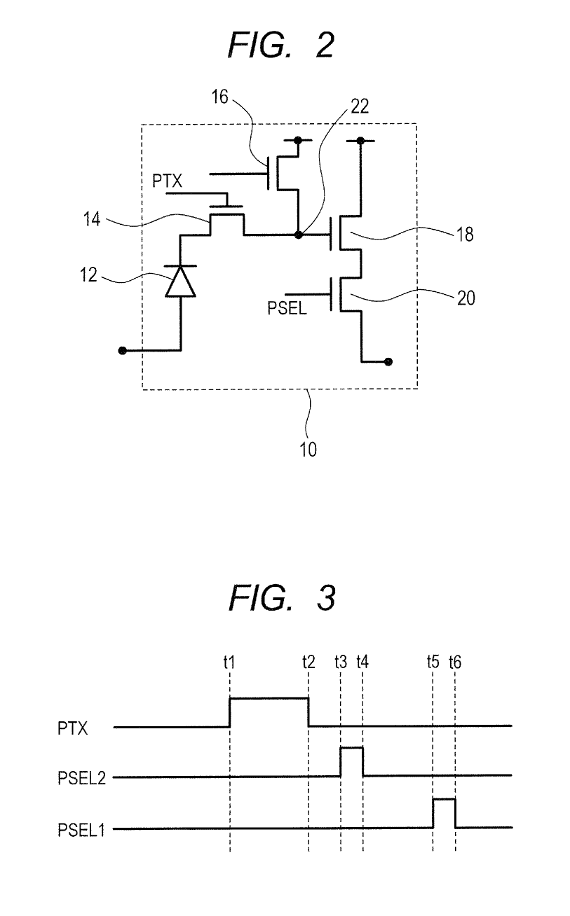

First, a construction of a solid-state imaging device according to the present embodiment will be described with reference to FIGS. 1 and 2. FIG. 1 is a circuit diagram illustrating an example of the construction of the solid-state imaging device according to the present embodiment. FIG. 2 is a circuit diagram illustrating an example of a construction of a unit pixel of the solid-state imaging device according to the present embodiment.

As illustrated in FIG. 1, a solid-state imaging device 100 according to the present embodiment has a pixel region including a pixel array in which a plurality of pixels 10 are arranged along the row direction and the column direction in a two-dimensional matrix form. Although the pixel region including the pixel array of (2 rows)×(4 columns) is illustrated in FIG. 1 in order to simplify the drawing, the number of rows and the number of columns of the pixel array are not limited to them. In the description, it is assumed that the row direction indicates the lateral direction in the drawings and the column direction indicates the longitudinal direction in the drawings. For example, the row direction corresponds to the horizontal direction in the solid-state imaging device and the column direction corresponds to the vertical direction in the solid-state imaging device.

As illustrated in FIG. 2, each pixel 10 has a photodiode 12 serving as a photoelectric conversion element, a transfer MOS transistor 14, a reset MOS transistor 16, an amplifier MOS transistor 18, and a select MOS transistor 20. In FIG. 1, for simplicity of the drawing, a specific circuit construction is illustrated with respect only to partial pixels 10 (a pixel 10-1 and a pixel 10-2) among the plurality of pixels 10.

A cathode of the photodiode 12 is connected to a source of the transfer MOS transistor 14. A drain of the transfer MOS transistor 14 is connected to a source of the reset MOS transistor 16 and a gate of the amplifier MOS transistor 18. A connection node of the drain of the transfer MOS transistor 14, the source of the reset MOS transistor 16, and the gate of the amplifier MOS transistor constructs a floating diffusion region (hereinbelow, referred to as an FD region) 22. A drain of the reset MOS transistor 16 and a drain of the amplifier MOS transistor 18 are connected to a power voltage line. A source of the amplifier MOS transistor 18 is connected to a drain of the select MOS transistor 20. The transfer MOS transistor 14, the reset MOS transistor 16, the amplifier MOS transistor 18, and the select MOS transistor 20 construct an intrapixel read-out circuit to read out the pixel signal based on electric charges generated in the photodiode 12. The select MOS transistor 20 is a pixel output portion for outputting a signal based on a signal generated by the photoelectric conversion element.

There is a case where the denominations of the source and drain of the transistor differ in accordance with a conductivity type of the transistor, a function to which attention is paid, or the like. There is also a case where the foregoing source and drain are called by opposite denominations. In the description, there is also a case where the transistor is called a switch. For example, there is also a case where the select MOS transistor 20 is expressed as a select switch.

A row select signal line 24 is arranged in each row of the pixel array so as to extend in the row direction. The row select signal line 24 is connected to a gate of the select MOS transistor 20 of each pixel 10 arranged in the row direction and forms a signal line which is common to these pixels 10. In FIG. 1, for convenience of the following description, the row select signal line 24 connected to the pixel 10 of the row to which the pixel 10-1 belongs is expressed as a row select signal line 24-1 and the row select signal line 24 connected to the pixel 10 of the row to which the pixel 10-2 belongs is expressed as a row select signal line 24-2, respectively.

A vertical shift register 26 is connected to the row select signal line 24. A select pulse signal PSEL to drive the select MOS transistor 20 is output from the vertical shift register 26. In this instance, it is assumed that when a signal at a High level (hereinbelow, referred to as “H level”) is supplied to the row select signal line 24, the select MOS transistor 20 is set into a conductive state (ON state). It is also assumed that when a signal at a Low level (hereinbelow, referred to as “L level”) is supplied to the row select signal line 24, the select MOS transistor 20 is set into a non-conductive state (OFF state). When distinguishing the select pulse signal PSEL which is supplied to the row select signal line 24-1 from the select pulse signal PSEL which is supplied to the row select signal line 24-2, it is assumed that the former signal is expressed as a select pulse signal PSEL1 and the latter signal is expressed as a select pulse signal PSEL2.

A vertical signal line 28 is arranged in each column of the pixel array so as to extend in the column direction. The vertical signal line 28 is connected to a source of each of the select MOS transistors 20 of the pixels 10 arranged in the column direction and forms a signal line common to these pixels 10. One end portion of the vertical signal line 28 is connected to one input terminal of a differential amplifier circuit 30 constructing a part of the read-out circuit.

A ground wiring 32 is arranged in each column of the pixel array so as to extend in the column direction. The ground wiring 32 is connected to an anode of each of the photodiodes 12 of the pixels 10 arranged in the column direction.

Both end portions of at least one of the ground wirings 32 provided in correspondence to the respective columns extend to peripheral portions of a chip and are connected to ground pads 34 arranged in the peripheral portions of the chip. FIG. 1 illustrates an example in which the ground pads 34 are connected onto an extension line of the ground wiring 32 connected to the pixels 10-1 and 10-2. In FIG. 1, for convenience of the following description, on the drawing, the upper ground pad 34 is expressed as a ground pad 34-1 and the lower ground pad 34 is expressed as a ground pad 34-2. The ground pads 34-1 and 34-2 are arranged on two opposite sides of the chip. The ground wirings 32 provided for the respective columns of the pixel array are electrically connected. In the example illustrated in FIG. 1, the ground wirings 32 form a mesh shape covering the pixel region.

A reference voltage wiring 36 extending in the column direction is arranged so as to perpendicularly cross the row direction of the pixel region. The reference voltage wiring 36 is connected to the other input terminals of the differential amplifier circuits 30. A reference voltage lead-out wiring 38 extending in the column direction is arranged at a position adjacent to the reference voltage wiring 36. A plurality of reference voltage wiring switches 40 are arranged electrically in parallel between the reference voltage wiring 36 and the reference voltage lead-out wiring 38. The reference voltage wiring 36 and the reference voltage lead-out wiring 38 can be connected at each position where the reference voltage wiring switch 40 is arranged.

The reference voltage wiring switch 40 is arranged at a row position corresponding to a connection portion of the pixel 10 (anode of the photodiode 12) of each row and the ground wiring 32. In FIG. 1, the switch arranged at the same row position as a connection portion C of the pixel 10-1 and the ground wiring 32 is expressed as a switch 40-1, and the switch 40 arranged at the same row position as a connection node B of the pixel 10-2 and the ground wiring 32 is expressed as a switch 40-2, respectively. The switch 40-1 can be controlled by the select pulse signal PSEL1 which is supplied to the row select signal line 24-1. The switch 40-2 can be controlled by the select pulse signal PSEL2 which is supplied to the row select signal line 24-2. It is now assumed that when the signal of the H level is supplied to the row select signal line 24, the reference voltage wiring switch 40 is set into the conductive state (ON state). It is also assumed that when the signal of the L level is supplied to the row select signal line 24, the reference voltage wiring switch 40 is set into the non-conductive state (OFF state). The reference voltage wiring switch 40 may be controlled by a signal different from the signal which is supplied to the row select signal line 24. The vertical shift register 26 is a control unit for controlling the select MOS transistors 20 and the reference voltage wiring switches 40.

Both end portions of the reference voltage lead-out wiring 38 are extended to the peripheral portions of the chip and are connected to reference voltage pads 42 arranged in the peripheral portions of the chip. In FIG. 1, for convenience of the following description, on the drawing, the upper reference voltage pad 42 is expressed as a reference voltage pad 42-1 and the lower reference voltage pad 42 is expressed as a reference voltage pad 42-2, respectively. The reference voltage pad 42-1 and the reference voltage pad 42-2 are arranged on the same two sides of the chip as the two sides on which the ground pads 34-1 and 34-2 are arranged.

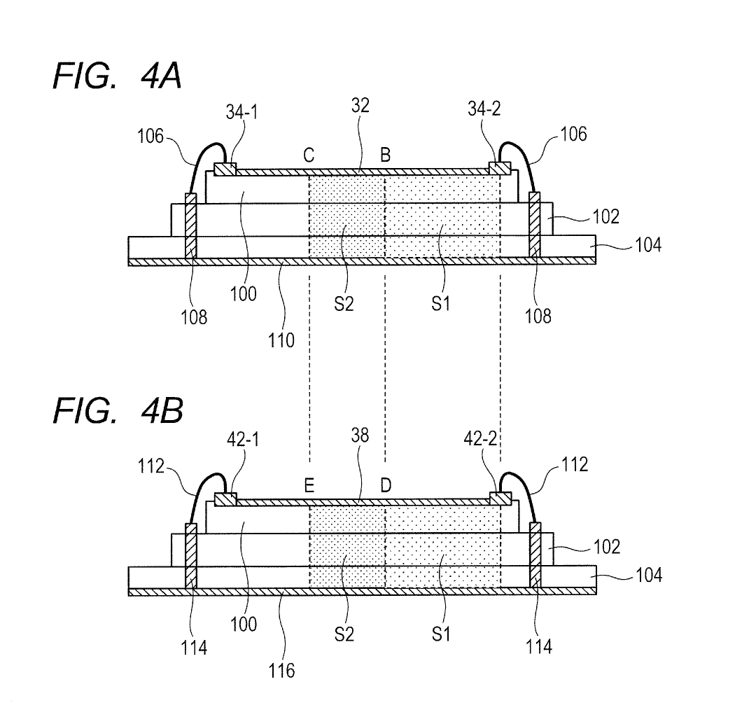

Subsequently, a method of driving the solid-state imaging device according to the present embodiment will be described with reference to FIGS. 1 to 4B. FIG. 3 is a timing chart illustrating a method of driving the solid-state imaging device according to the present embodiment. FIGS. 4A and 4B are cross-sectional views illustrating cross-sectional structures of the solid-state imaging device in a state where it has been put on an external substrate. In the following description, the operation serving as a feature of the invention will be described as a center and a description about portions to which the well-known techniques can be applied such as reset operation of the photodiode 12 and the FD region 22, operation of the read-out circuit after the differential amplifier circuit 30, and the like is properly omitted here.

When light (optical image of an object to be photographed) enters the solid-state imaging device 100, signal charges are generated by the photoelectric conversion in the photodiode 12 of each pixel 10.

For a time interval between time t1 and time t2, a transfer pulse signal PTX of the H level is supplied to a gate of the transfer MOS transistor 14. Thus, the transfer MOS transistor 14 is turned on (ON state) and the signal charges generated by the photodiode 12 are transferred to the FD region 22.

The transfer MOS transistor 14 of the row to which the pixel 10-2 belongs and the transfer MOS transistor 14 of the row to which the pixel 10-1 belongs may be simultaneously or individually driven by the transfer pulse signal PTX. In the case of individually driving those rows, for example, the row to which the pixel 10-2 belongs is driven at the timing of the transfer pulse signal PTX and the row to which the pixel 10-1 belongs is driven at timing between time t4 and time t5.

Subsequently, for a time interval between time t3 and time t4, the select pulse signal PSEL2 of the H level is supplied to the row select signal line 24-2, thereby turning on the select MOS transistor 20 of the pixel 10 connected to the row select signal line 24-2. Thus, an output signal of the amplifier MOS transistor 18 based on the electric potential according to the signal charges transferred to the FD region 22 is output to the vertical signal line 28 via the select MOS transistor 20. A pixel signal voltage in which a voltage at the position B of the ground wiring 32 is set to a reference is output to the vertical signal line 28 connected to the pixel 10-2. The pixel signal voltage output from the pixel 10-2 is input to the one input terminal of the differential amplifier circuit 30 via the vertical signal line 28.

A reference voltage has been applied to the reference voltage pad 42-1 and the reference voltage pad 42-2. When the select pulse signal PSEL2 of the H level is supplied to the row select signal line 24-2, the reference voltage wiring switch 40-2 is turned on, so that the reference voltage lead-out wiring 38 and the reference voltage wiring 36 are connected at a position D. Thus, a voltage at the position D of the reference voltage lead-out wiring 38 is applied to the reference voltage wiring 36 and this voltage is input to the other input terminal of the differential amplifier circuit 30.

Consequently, the differential amplifier circuit 30 amplifies a voltage as a difference between the pixel signal voltage input to the one input terminal and the reference voltage input to the other input terminal and outputs the amplified voltage from an output terminal.

An example of a cross-sectional structural diagram including the solid-state imaging device 100, a package 102 for holding it, and an external substrate 104 to which the package 102 is connected is illustrated in FIGS. 4A and 4B. FIG. 4A is the cross-sectional view taken along the ground wiring 32. FIG. 4B is the cross-sectional view taken along the reference voltage lead-out wiring 38. FIGS. 4A and 4B correspond to the schematic cross sectional views of the solid-state imaging device 100 viewed from the left side in FIG. 1.

As illustrated in FIG. 4A, the ground pads 34-1 and 34-2 of the solid-state imaging device 100 are connected to an external ground wiring 110 of the external substrate 104 via bonding wires 106 and viaholes 108 formed in the package 102. Thus, a ground loop including the ground wiring 32 and the external ground wiring 110 is formed.

Similarly, as illustrated in FIG. 4B, the reference voltage pads 42-1 and 42-2 of the solid-state imaging device 100 are connected to an external reference voltage wiring 116 of the external substrate 104 via bonding wires 112 and viaholes 114 formed in the package 102. Thus, a reference voltage wiring loop including the reference voltage wiring 38 and the external reference voltage wiring 116 is formed.

As mentioned above, when the select pulse signal PSEL2 of the H level is supplied to the row select signal line 24-2, the pixel signal voltage from the pixel 10-2 is output while setting the position B on the ground wiring 32 to a reference. Therefore, a region of the ground loop which exerts an influence on the electric potential at the position B of the ground wiring 32 becomes a region of an area S1 illustrated in FIG. 4A.

At the same time, when the select pulse signal PSEL2 of the H level is supplied to the row select signal line 24-2, the reference voltage wiring switch 40-2 is also turned on in association with it, so that the reference voltage wiring 36 and the reference voltage lead-out wiring are electrically connected at a position D. At this time, since the position D viewed from the left side in FIG. 1 overlaps with the position B, a region of the reference voltage loop which exerts an influence on the electric potential at the position D of the reference voltage wiring 36 also becomes a region of the area S1 illustrated in FIG. 4B.

When an external magnetic field in the direction which crosses the paper surface is presumed in FIGS. 4A and 4B, a magnetically induced voltage which is induced in each of the ground wiring 32 and the reference voltage wiring 36 by the external magnetic field is proportional to the area of the each loop. Since the areas of the respective loops are equal to S1, the magnetically induced voltage which is induced in the ground wiring 32 and the magnetically induced voltage which is induced in the reference voltage wiring 36 have the same value. That is, the magnetically induced voltage which is superimposed to the pixel signal voltage which is input from the pixel 10-2 to the differential amplifier circuit 30 through the vertical signal line 28 and the magnetically induced voltage which is superimposed to the reference voltage which is input to the differential amplifier circuit 30 through the reference voltage wiring 36 are equal. Therefore, those magnetically induced voltages are cancelled each other by the differential amplifier circuit 30 which amplifies the difference between those two input voltages. The component of the magnetically induced voltage superimposed to the input voltage does not appear in an output signal of the differential amplifier circuit 30.

Subsequently, for a time interval between time t5 and time t6, the select pulse signal PSEL1 of the H level is supplied to the row select signal line 24-1, thereby turning on the select MOS transistor 20 of the pixel 10 connected to the row select signal line 24-1. Thus, the output signal of the amplifier MOS transistor 18 based on the electric potential according to the signal charges transferred to the FD region 22 is output to the vertical signal line 28 through the select MOS transistor 20. A pixel signal voltage in which a voltage at the position C of the ground wiring 32 is set to a reference is output to the vertical signal line 28 connected to the pixel 10-1. The pixel signal voltage output from the pixel 10-1 is input to the one input terminal of the differential amplifier circuit 30 through the vertical signal line 28. At this time, a region of the ground loop which exerts an influence on the electric potential at the position C of the ground wiring 32 becomes a region of an area (S1+S2) illustrated in FIG. 4A.

On the other hand, a reference voltage has been applied to the reference voltage pads 42-1 and 42-2. When the select pulse signal PSEL1 of the H level is supplied to the row select signal line 24-1, the reference voltage wiring switch 40-1 is turned on and the reference voltage lead-out wiring 38 and the reference voltage wiring 36 are connected at a position E. Thus, a voltage at the position E of the reference voltage lead-out wiring 38 is applied to the reference voltage wiring 36 and this voltage is input to the other input terminal of the differential amplifier circuit 30. At this time, since the position E view from the left side in FIG. 1 overlaps with the position C, a region of the reference voltage loop which exerts an influence on the electric potential at the position E of the reference voltage wiring 36 also becomes a region of the area (S1+S2) illustrated in FIG. 4B.

Consequently, the differential amplifier circuit 30 amplifies a voltage as a difference between the pixel signal voltage input to the one input terminal and the reference voltage input to the other input terminal and outputs the amplified voltage from an output terminal.

When the external magnetic field in the direction which crosses the paper surface is presumed in FIGS. 4A and 4B, the magnetically induced voltage which is induced in each of the ground wiring 32 and the reference voltage wiring 36 is proportional to the area of each loop. Since the areas of the respective loops are equal to (S1+S2), the magnetically induced voltage which is induced in the ground wiring 32 and the magnetically induced voltage which is induced in the reference voltage wiring 36 have the same value. That is, the magnetically induced voltage which is superimposed to the pixel signal voltage which is input from the pixel 10-1 to the differential amplifier circuit 30 through the vertical signal line 28 and the magnetically induced voltage which is superimposed to the reference voltage which is input to the differential amplifier circuit 30 through the reference voltage wiring 36 are equal. Therefore, those magnetically induced voltages are cancelled by the differential amplifier circuit 30 which amplifies the difference between those two input voltages. The component of the magnetically induced voltage superimposed to the input voltage does not appear in the output signal of the differential amplifier circuit 30.

As mentioned above, by switching the position where the reference voltage wiring 36 and the reference voltage lead-out wiring 38 are connected in accordance with the position of the row to be read out, the magnetically induced voltage which is superimposed to the ground wiring and the magnetically induced voltage which is superimposed to the reference voltage lead-out wiring 38 can be equalized. Thus, the magnetically induced voltage which is superimposed to the ground wiring 32 and the magnetically induced voltage which is superimposed to the reference voltage lead-out wiring 38 can be cancelled by the differential amplifier circuit 30, and noises which are superimposed to the output signal can be suppressed.

As mentioned above, according to the present embodiment, since the connection portion of the reference voltage wiring and the reference voltage lead-out wiring is switched in accordance with the position of the reading-out row of the pixel, the magnetically induced voltage which is superimposed to the pixel output voltage and the magnetically induced voltage which is superimposed to the reference voltage can be equalized. Thus, those magnetically induced voltages can be cancelled by the differential amplifier circuit and the noise component caused by the external magnetic field in the output signal can be remarkably reduced.

Although the example in which the pixel 10 has the select MOS transistor 20 has been described in the present embodiment. The present embodiment may be constructed in such a manner that the pixel 10 does not have the select MOS transistor 20 but the electric potential in the FD region 22 connected to the amplifier MOS transistor 18 in the case of the pixel 10 for reading out the signal and that in the case of each of the other pixels 10 are made different. That is, it is sufficient that the electric potential in the FD region 22 of the pixel 10 which became the order for reading out the signal is set to such an electric potential that the amplifier MOS transistor 18 is made operative and the electric potential of each of the other pixels 10 is set to such an electric potential that the amplifier MOS transistor 18 is made inoperative. In the case of such a construction, a first voltage for making the amplifier MOS transistor 18 operative and a second voltage for making it inoperative are selectively supplied to the reset MOS transistor 16 from the power voltage line. In this case, it is sufficient to set any one of a plurality of reference voltage wiring switches 40 from the OFF state to the ON state in accordance with the position of the signal reading-out pixel 10 in association with the control to switch the voltage which is supplied to the reset MOS transistor 16 from the second voltage to the first voltage. In this case, the amplifier MOS transistor 18 becomes a pixel output portion for outputting a signal based on the signal generated by the photoelectric conversion element.

A length of the electric path from the ground pad 34 to the pixel 10 is shortened due to the position of the pixel 10 selected by the vertical shift register 26. In the present embodiment, the example in which the length of the electric path from the reference voltage pad 42 to the differential amplifier circuit 30 through the reference voltage lead-out wiring 38 is shortened in accordance with it has been described. However, the above case is an example and, for instance, a length of wirings for supplying the power voltage to the reset MOS transistor 16 and the amplifier MOS transistor 18 becomes short in accordance with the position of the pixel 10 selected by the vertical shift register 26. Therefore, the length of the electric path from the pad 42 for the reference voltage to the differential amplifier circuit 30 through the reference voltage lead-out wiring 38 may be shortened in accordance with the position of the selected pixel 10. In the solid-state imaging device of the present embodiment, the vertical signal line 28 is extended in the same direction as the direction along which the reference voltage lead-out wiring 38 is extended. In accordance with such a situation that the length of the electric path from the pixel output portion to the differential amplifier circuit 30 becomes short in accordance with the position of the pixel 10 selected by the vertical shift register 26, the length of the electric path from the pad 42 for the reference voltage to the differential amplifier circuit 30 through the reference voltage lead-out wiring 38 is shortened. Consequently, the differential amplifier circuit 30 can output the signal in which the noises due to the external magnetic field caused in the vertical signal line 28 have been reduced.

In the present embodiment, the example in which the ground wiring 32 is extended in the same direction as the direction of the reference voltage lead-out wiring 38 has been mentioned. As for the same direction, it is sufficient that the ground wiring 32 is arranged at an inclination angle within ±10° from the reference voltage lead-out wiring 38. It is also sufficient that the vertical signal line 28 is arranged at an inclination angle within ±10° from the reference voltage lead-out wiring 38.

Although the example in which the vertical scanning circuit for controlling the pixels 10 and the reference voltage wiring switch 40 is the shift register has been described in the present embodiment, it may be a decoder. A circuit for controlling the reference voltage wiring switch 40 may be provided separately from the vertical scanning circuit for controlling the pixels 10.

### Second Embodiment

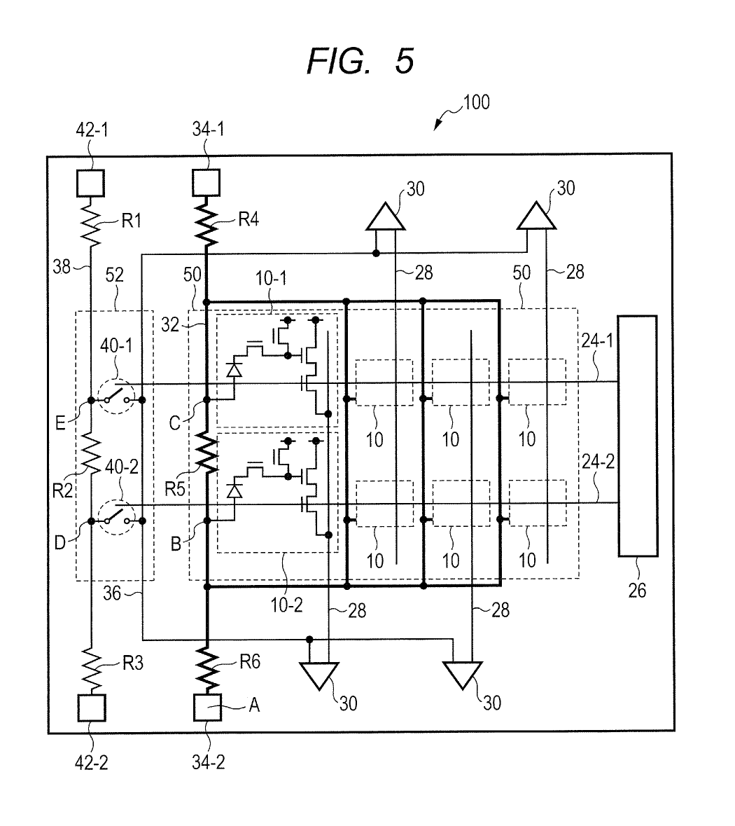

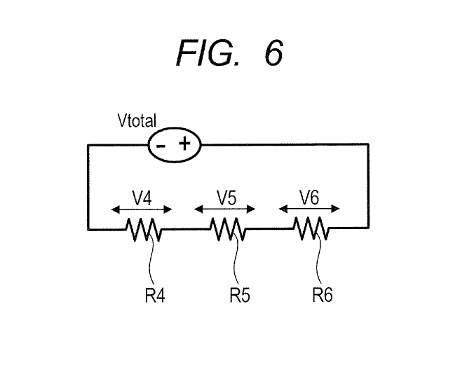

A solid-state imaging device and a method of driving the same according to the second embodiment of the present invention will be described with reference to FIGS. 5 and 6. Component elements similar to those in the solid-state imaging device and the method of driving the same according to the first embodiment illustrated in FIGS. 1 to 4B are designated by the same reference numerals and their description is omitted or will be simply made.

FIG. 5 is a schematic diagram illustrating a construction of the solid-state imaging device according to the present embodiment. FIG. 6 is a schematic diagram illustrating a relation between the total magnetically induced voltage which is induced in the ground wiring and the magnetically induced voltage which is generated in each region of the ground wiring.

A fundamental construction of the solid-state imaging device 100 according to the present embodiment is similar to that of the solid-state imaging device 100 illustrated in FIG. 1. In the embodiment, an example of a construction of the ground wiring 32 and the reference voltage wiring 36 to effectively reduce the noises which are superimposed to the output signal will be described.

As mentioned above, the magnetically induced voltage which is induced on the wiring forming the ground loop is proportional to the area of the ground loop. Similarly, the magnetically induced voltage which is induced on the wiring forming the reference voltage loop is proportional to the area of the reference voltage loop. Therefore, by arranging the wirings and switches so that the areas of those loops are equalized, the magnetically induced voltage which is superimposed to the output signal of the differential amplifier circuit 30 can be reduced.

However, the voltage serving as a reference of the pixel output voltage which is read out of the pixel 10 is a voltage at the position B or C of the ground wiring 32. The reference voltage which is input to the differential amplifier circuit 30 is a voltage at the position D or E of the reference voltage lead-out wiring 38. Those voltages change even by distribution of wiring resistances of the ground wiring 32 and the reference voltage lead-out wiring 38. Therefore, even if the area of the ground loop and the area of the reference voltage loop are equal, a case where the magnetically induced voltage which is superimposed to the pixel output signal and the magnetically induced voltage which is superimposed to the reference voltage differ can occur. In such a case, such a situation that the magnetically induced voltage which is superimposed to the output voltage cannot be sufficiently cancelled by the differential amplifier circuit 30 is also presumed.

Therefore, in the solid-state imaging device according to the present embodiment, in addition to the equalization of the areas of the loops, the magnetically induced voltage which is superimposed to the output signal of the differential amplifier circuit 30 is more effectively suppressed also in consideration of the ratio of the wiring resistances in the ground wiring 32 and the reference voltage lead-out wiring 38. Specifically speaking, the ground wiring 32 and the reference voltage lead-out wiring 38 are arranged by the following method.

Now, the ground wiring 32 is divided into a region between the ground pad 34-1 and a pixel region 50, a region in the pixel region 50, and a region between the pixel region 50 and the ground pad 34-2 as illustrated in FIG. 5 and is considered. It is assumed that wiring resistances of those regions are represented by R4, R5, and R6, respectively. The wiring resistance mentioned here is a lumped equivalent resistance of each region.

Now, assuming that a total magnetically induced voltage which is induced in the ground loop formed by the ground wirings 32 and 110 in and out of the solid-state imaging device 100 is set to Vtotal, relations among magnetically induced voltages V4, V5, and V6 which appear in the wiring resistors R4, R5, and R6 are shown almost as illustrated in FIG. 6. Therefore, a magnetically induced voltage Vgnd (=V5) which appears in the ground wiring 32 in the pixel region 50 is expressed by the following equation:

Vgnd=Vtotal×R5/(R4+R5+R6).

Similarly, the reference voltage lead-out wiring 38 is divided into a switch circuit region 52 in which the plurality of reference voltage wiring switches 40 are formed, a region between the pad 42-1 for the reference voltage and the switch circuit region 52, and a region between the switch circuit region 52 and the pad 42-1 for the reference voltage and is considered. It is assumed that wiring resistances (lumped equivalent resistances) of those regions are represented by R1, R2, and R3, respectively.

At this time, a magnetically induced voltage Vref which is generated in the reference voltage lead-out wiring in the switch circuit region 52 is expressed by the following equation in a manner similar to the case of the magnetically induced voltage Vgnd:

Vref=Vtotal×R2/(R1+R2+R3).

As mentioned above, the magnetically induced voltage which is superimposed to the output signal of the differential amplifier circuit 30 is a difference between the magnetically induced voltage which is induced on the ground wiring 32 and the magnetically induced voltage which is induced on the reference voltage lead-out wiring 38. Therefore, if the magnetically induced voltage Vgnd and the magnetically induced voltage Vref are equal, the magnetically induced voltage which is superimposed to the output signal of the differential amplifier circuit 30 can be cancelled. That is, it is desirable that the wiring resistances R4, R5, and R6 of the ground wiring 32 and the wiring resistances R1, R2, and R3 of the reference voltage lead-out wiring 38 satisfy the following relation:

R5/(R4+R5+R6)≈R2/(R1+R2+R3).

In other words, a ratio of the wiring resistance in the pixel region 50 to the wiring resistance between the ground pads of the ground wiring 32 and a ratio of the wiring resistance in the switch circuit region 52 to the wiring resistance between the pads for the reference voltage of the reference voltage wiring 36 are equalized. Thus, the magnetically induced voltage which is superimposed to the output signal of the differential amplifier circuit 30 can be effectively reduced.

As an example, the wiring resistances R1, R2, R3, R4, R5, and R6 can be changed by increasing or decreasing wiring widths of the ground wiring 32 and the reference voltage lead-out wiring 38 in accordance with the regions.

As mentioned above, according to the present embodiment, since the connection portion of the reference voltage wiring and the reference voltage lead-out wiring is switched in accordance with the position of the reading-out row of the pixel, the magnetically induced voltage which is superimposed to the pixel output voltage and the magnetically induced voltage which is superimposed to the reference voltage can be equalized. Thus, those magnetically induced voltages can be cancelled by the differential amplifier circuit and the noise component caused by the external magnetic field in the output signal can be remarkably reduced.

Since the ratio of the wiring resistances in the pixel region which occupy in the ground wiring and the ratio of the wiring resistances in the switch circuit which occupy in the reference voltage wiring are equalized, the magnetically induced voltage which is superimposed to the output signal can be more effectively suppressed.

### Third Embodiment

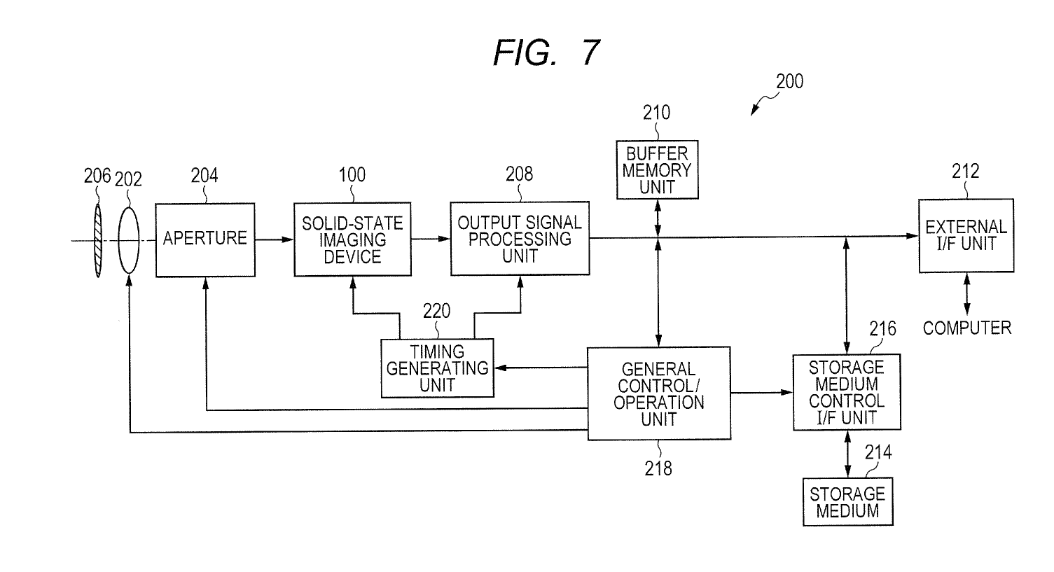

An imaging system according to the third embodiment of the present invention will be described with reference to FIG. 7. Component elements similar to those in the solid-state imaging devices according to the first and second embodiments illustrated in FIGS. 1 to 6 are designated by the same reference numerals and their description is omitted or will be simply made.

FIG. 7 is a block diagram illustrating a construction of the imaging system according to the present embodiment.

The solid-state imaging devices described in the foregoing first and second embodiments can be applied to various kinds of imaging systems. As an example of the imaging systems, a digital still camera, a digital camcorder, a surveillance camera, or the like can be mentioned.

An imaging system 200 illustrated as an example in FIG. 7 has the solid-state imaging device 100, a lens 202 for focusing an optical image of an object onto the solid-state imaging device 100, an aperture 204 for making an amount of light which passes through the lens 202 variable, and a barrier 206 for protecting the lens 202. The lens 202 and the aperture 204 are an optical system for converging the light onto the solid-state imaging device 100.

The imaging system 200 also has an output signal processing unit 208 for processing the output signal which is output from the solid-state imaging device 100.

The output signal processing unit 208 performs an AD conversion for converting the analog signal which is output from the solid-state imaging device 100 into a digital signal. Besides, the output signal processing unit 208 also executes an operation for performing various kinds of corrections and compressions in accordance with necessity and outputting image data.

The imaging system 200 further has a buffer memory unit 210 for temporarily storing the image data, and an external interface unit (external I/F unit) 212 for communicating with an external computer or the like. Moreover, the imaging system 200 has a storage medium 214 such as a semiconductor memory or the like for recording or reading out the image pickup data, and a storage medium control interface unit (storage medium control I/F unit) 216 for recording or reading out the image pickup data onto/from the storage medium 214. The storage medium 214 may be built in the imaging system 200 or may be detachable therefrom.

Further, the imaging system 200 has a general control/operation unit 218 for performing various kinds of arithmetic operations and controlling the whole digital still camera, and a timing generating unit 220 for generating various kinds of timing signals to the solid-state imaging device 100 and the output signal processing unit 208. The timing signals or the like may be input from the outside and it is sufficient that the imaging system 200 has at least the solid-state imaging device 100, and the output signal processing unit 208 for processing the output signal generated from the solid-state imaging device 100.

In the case of the solid-state imaging device 100 for performing an imaging-plane phase difference AF, the solid-state imaging device 100 outputs a signal for focus detection based on a signal which is output from a pixel for focus detection and an image pickup signal to the output signal processing unit 208. By using the signal for focus detection, the output signal processing unit 208 detects whether or not the image is in-focused. The output signal processing unit 208 generates an image by using the image pickup signal. If the output signal processing unit 208 detects that the image is not focused, the general control/operation unit 218 drives the optical system in the in-focus direction. By using the signal for focus detection which is output from the solid-state imaging device 100, the output signal processing unit 208 detects again whether or not the image is in-focused. After that, the solid-state imaging device 100, the output signal processing unit 208, and the general control/operation unit 218 repeat the foregoing operations until the image is in-focused.

As mentioned above, the imaging system of the present embodiment can execute the imaging operation by using the solid-state imaging device 100. By constructing the imaging system by using the solid-state imaging device 100 according to the first or second embodiment, the imaging system of a high S/N ratio and high performance can be realized.

[Modifications]

The invention is not limited to the foregoing embodiments but various modifications are possible.

For example, although the example in which the reference voltage wiring switch 40 is arranged at the row position corresponding to the connection portion of the photodiode 12 and the ground wiring 32 has been shown in the foregoing embodiments, it is not always necessary to strictly arrange the reference voltage wiring switch 40 at the row position corresponding to the connection portion. It is sufficient that the reference voltage wiring switch 40 is arranged at a position where the magnetically induced voltage which is superimposed to the vertical signal line and the magnetically induced voltage which is superimposed to the reference voltage wiring 36 are equalized and may be arranged at a position which is deviated to the front or rear in the column direction from the connection portion. Typically, the reference voltage wiring switch 40 can be arranged within a range of the row position where the pixel 10 as a reading-out target is located.

Although the example in which the reference voltage wiring switch 40 is driven by the select pulse signal PSEL which is supplied to the row select signal line 24 has been shown in the embodiments, the reference voltage wiring switch 40 may be driven by a control signal different from the select pulse signal PSEL. Also in this case, it is sufficient that the reference voltage wiring switch 40 arranged at almost the same position as that of the selected row is turned on and the extracted reference voltage is input to the other input terminal of the differential amplifier circuit 30 through this switch. This is true of the case of reading out another row.

The circuit construction disclosed in the foregoing embodiments can be also applied to a solid-state imaging device in which a sample and hold circuit is added between the reference voltage wiring and the reference voltage lead-out wiring.

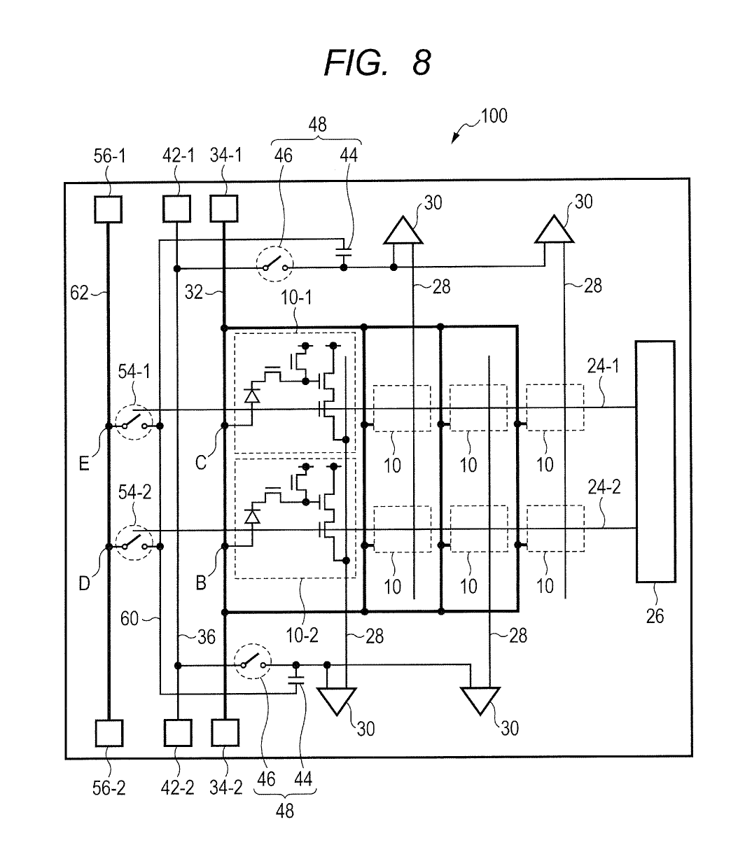

For example, as illustrated in FIG. 8, a sample and hold circuit 48 including a hold capacitor 44 to hold the reference voltage and a switch 46 can be added between the reference voltage wiring 36 and the differential amplifier circuit 30. When the signal is read out, the reference voltage is held by the hold capacitor 44 and the differential amplifier circuit 30 is disconnected from the reference voltage wiring 36 by the switch 46, so that an influence by the noises from the reference voltage wiring 36 can be eliminated.

However, if the reference voltage is held by the hold capacitor 44, the magnetically induced voltage which is induced in the ground wiring 32 of the pixel 10 cannot be cancelled by the differential amplifier circuit 30. In such a case, by providing a lead-out circuit similar to the reference voltage wiring 36 in the embodiment for a ground wiring 60 of the hold capacitor 44, an effect similar to that in the embodiment can be obtained.

In the solid-state imaging device 100 illustrated in FIG. 8, a ground lead-out wiring 62 whose both ends are connected to ground pads 56-1 and 56-2 is provided at a position adjacent to the ground wiring 60 of the hold capacitor 44. A plurality of ground wiring switches 54 are arranged between the ground wiring 60 and the ground lead-out wiring 62 in correspondence to the row positions. By equalizing an area of a ground loop of the ground wiring of the hold capacitor 44 and an area of a ground loop of the ground wiring of the pixel 10, magnetically induced voltages which are generated in those ground loops are equalized and can be cancelled by the differential amplifier circuit 30.

The construction of the pixel 10 illustrated in FIG. 2 is an example and the pixel which can be applied to the solid-state imaging device of the invention is not limited to such a pixel.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-140480, filed on Jul. 8, 2014, which is hereby incorporated by reference herein in its entirety.

What is claimed is:

1. A solid-state imaging device comprising:
a first pixel and a second pixel each of which has a photoelectric conversion element and a pixel output portion for outputting a signal based on a signal generated by the photoelectric conversion element and which are arranged in a first direction;
a first wiring which is connected to the pixel output portion of each of the first pixel and the second pixel and is arranged along the first direction;
a differential amplifier circuit in which one input terminal is connected to the first wiring and a length of an electric path of the first wiring from the one input terminal to the pixel output portion of the second pixel is longer than a length of an electric path of the first wiring from the one input terminal to the pixel output portion of the first pixel;
a second wiring connected to the other input terminal of the differential amplifier circuit;
a first pad to which a voltage is supplied;
a third wiring which is formed along the first direction and is connected to the first pad;
a first switch arranged on an electric path between the second wiring and the third wiring;
a second switch which is arranged on the electric path between the second wiring and the third wiring electrically in parallel with the first switch and in which a length of an electric path from the other input terminal to the first pad via the second wiring and the third wiring is longer than that in the case where the first switch is in ON state; and
a control unit configured to control the first switch to be ON state and the second switch to be OFF state in a case the pixel output portion of the first pixel outputs the signal to the first wiring, and to control the second switch to be ON state and the first switch to be OFF state in a case the pixel output portion of the second pixel outputs the signal to the first wiring.

2. The solid-state imaging device according to claim 1, further comprising:
a second pad to which a voltage is supplied; and
a fourth wiring connected to the photoelectric conversion element of each of the first pixel and the second pixel and the second pad,
wherein the first pad and the second pad are arranged on a same side of a chip.

3. The solid-state imaging device according to claim 2, wherein
the first pad and the second pad are arranged on two opposite sides of a chip, respectively, and
a ratio of a wiring resistance of the fourth wiring in the pixel region in which the plurality of pixels are arranged to a wiring resistance of the fourth wiring between the two second pads and a ratio of a wiring resistance of the third wiring in the region in which the first and second switches are formed to a wiring resistance of the third wiring between the two first pads are equal.

4. The solid-state imaging device according to claim 2, wherein
the fourth wiring is formed so as to extend in the first direction.

5. The solid-state imaging device according to claim 3, wherein
the fourth wiring is formed so as to extend in the first direction.

6. The solid-state imaging device according to claim 1, wherein
the control unit
controls the pixel output portion of the first pixel and the first switch by a common signal, and
controls the pixel output portion of the second pixel and the second switch by a common signal.

7. A method of driving a solid-state imaging device including
a first pixel and a second pixel each of which has a photoelectric conversion element and a pixel output portion for outputting a signal based on a signal generated by the photoelectric conversion element and which are arranged in a first direction;
a first wiring which is connected to the pixel output portion of each of the first pixel and the second pixel and is arranged along the first direction;
a differential amplifier circuit in which one input terminal is connected to the first wiring and a length of an electric path of the first wiring from the one input terminal to the pixel output portion of the second pixel is longer than a length of an electric path of the first wiring from the one input terminal to the pixel output portion of the first pixel;
a second wiring connected to the other input terminal of the differential amplifier circuit; and
a third wiring which is formed along the first direction and is connected to a first pad, wherein the method comprises:
setting a length of the electric path from the other input terminal to the first pad through the third wiring to a first length in the case where the pixel output portion of the first pixel outputs the signal to the first wiring, and
setting a length of the electric path from the other input terminal to the first pad through the third wiring to a second length longer than the first length in the case where the pixel output portion of the second pixel outputs the signal to the first wiring.

8. An imaging system comprising:
the solid-state imaging device according to claim 1; and
an optical system for focusing an image of an object to the solid-state imaging device.
